(19) United States
(12) Patent Application Publication
(10) Pub. No.: US 2022/0013914 A1
(43) Pub. Date: Jan. 13, 2022

(54) ANTENNA APPARATUS

(71) Applicant: SAMSUNG ELECTRO-MECHANICS CO., LTD., Suwon-si (KR)

(72) Inventors: Myeong Woo HAN, Suwon-si (KR); Youngsik HUR, Suwon-si (KR); Se Jong KIM, Suwon-si (KR); Wongi KIM, Suwon-si (KR); Woncheol LEE, Suwon-si (KR); Jeongki RYOO, Suwon-si (KR); Jinseon PARK, Suwon-si (KR); Soo-Ki CHOI, Suwon-si (KR); Hotaek SONG, Suwon-si (KR)

(73) Assignee: SAMSUNG ELECTRO-MECHANICS CO., LTD., Suwon-si (KR)

(21) Appl. No.: 17/034,843

(22) Filed: Sep. 28, 2020

(30) Foreign Application Priority Data
Jul. 8, 2020 (KR) 10-2020-0084286

(51) Int. Cl. H01Q 9/04; H01Q 1/50

(52) U.S. Cl. CPC H01Q 9/0485; H01Q 1/50

(57) ABSTRACT

An antenna apparatus including: a first insulation layer defining a cavity; an antenna and an electronic element disposed in the cavity of the first insulation layer; a second insulation layer disposed on a first surface facing a first direction among surfaces of the antenna and on a second surface facing the first direction among surfaces of the electronic element; and a connection wire disposed on a third surface facing the first direction among surfaces of the second insulation layer and configured to electrically connect the antenna and the electronic element. The connection wire is disposed on the second insulation layer, is disposed within a first contact hole overlapping the electronic element, and overlaps the antenna.

### CROSS-REFERENCE TO RELATED APPLICATION

This application claims priority to and the benefit under 35 USC 119(a) of Korean Patent Application No. 10-2020-0084286, filed in the Korean Intellectual Property Office on Jul. 8, 2020, the entire contents of which are incorporated herein by reference for all purposes.

### BACKGROUND

### 1. Field

The following description relates to an antenna apparatus.

### 2. Description of the Background

In general, an antenna apparatus includes an antenna, and an electronic element that transfers a signal to the antenna.

In general, an antenna and an electronic element that transfers a signal to the antenna are formed on separate layers, and then connected to each other through an electrical connection member such as a solder ball.

As described above, when the antenna and the electronic element are connected to each other through the electrical connection member, the antenna and the electronic element may not be correctly connected due to a positional alignment error of the electrical connection member, thereby deteriorating characteristics of the antenna, or generating an antenna loss through the electrical connection member. In addition, when it has a structure in which the antenna, the electrical connection member, and the electronic element are stacked, a volume of the antenna apparatus may be increased.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

An antenna apparatus capable of connecting an antenna and an electronic element without using an additional electrical connection member and reducing a volume of the antenna apparatus.

In one general aspect, an antenna apparatus includes: a first insulation layer defining a cavity; an antenna and an electronic element disposed in the cavity of the first insulation layer; a second insulation layer disposed on a first surface facing a first direction among surfaces of the antenna and on a second surface facing the first direction among surfaces of the electronic element; and a connection wire disposed on a third surface facing the first direction among surfaces of the second insulation layer and configured to electrically connect the antenna and the electronic element. The connection wire is disposed on the second insulation layer, is disposed within a first contact hole overlapping the electronic element, and overlaps the antenna.

The second insulation layer may have a second contact hole overlapping the antenna, and the antenna and the electronic element may be connected to each other through the first contact hole, the second contact hole, and the connection wire.

The connection wire may be disposed to contact the third surface of the second insulation layer closest to the first surface of the antenna and the second surface of the electronic element.

The antenna may be a dielectric material resonator antenna.

The connection wire may overlap the antenna along the first direction.

The antenna apparatus may further include a connection layer disposed between the connection wire and the antenna, and having a slot, and the slot of the connection layer may overlap the antenna along the first direction.

The antenna and the electronic element may be separated by a side wall, and the side wall may include the first insulation layer.

The first insulation layer may include a first sublayer, a second sublayer, and an intermediate layer disposed between the first sublayer and the second sublayer.

The cavity of the first insulation layer may include a first cavity and a second cavity separated from the first cavity, the first cavity may be formed in the first sublayer, the intermediate layer, and the second sublayer, the second cavity may be formed in the first sublayer, the antenna may be disposed in the first cavity, and the electronic element may be disposed in the second cavity.

A fourth surface facing the first direction among the surfaces of the first insulation layer may be coplanar with the first surface of the antenna and the second surface of the electronic element.

In another general aspect, an antenna apparatus includes: a first insulation layer; an antenna disposed within a first cavity of the first insulation layer; an electronic element disposed in a second cavity of the first insulation layer; a connection wire configured to electrically connect the antenna and the electronic element; and a second insulation layer disposed between the antenna, the electronic element, and the connection wire, and having a first contact hole overlapping the antenna and a second contact hole overlapping the electronic element, wherein the antenna is connected to the electronic element through the first contact hole, the connection wire, and the second contact hole.

The connection wire may be disposed to contact a second insulation layer closest to the surface of the antenna and the surface of the electronic element.

In another general aspect, an antenna apparatus includes an antenna disposed in a first cavity of an insulation layer; an electronic element disposed in a second cavity of the insulation layer such that a first surface of the electronic element is coplanar with a first surface of the antenna; and a connection wire disposed opposite the first surface of the antenna and the first surface of the electronic element and configured to electrically connect the antenna and the electronic element.

The antenna apparatus may include a connector disposed opposite the first surface of the antenna and the first surface of the electronic element, and the connection wire may be disposed within an insulation layer of the connector.

The antenna and the electronic element may be connected to each other without using an additional connection member, and the volume of the antenna apparatus may be reduced.

Other features and aspects will be apparent from the following detailed description, the drawings, and the claims.

### BRIEF DESCRIPTION OF THE DRAWINGS

FIG. 1 conceptually illustrates a flat surface of an antenna apparatus according to an example.

FIG. 2 conceptually illustrates a flat surface of an antenna apparatus according to another example.

FIG. 3 conceptually illustrates a flat surface of an antenna apparatus according to another example.

FIG. 4 conceptually illustrates an example of a structure of an antenna according to an example.

FIG. 5 conceptually illustrates an example of a structure of an antenna according to another example.

FIG. 6 illustrates a cross-sectional view of an antenna apparatus according to an example.

FIG. 7 illustrates a cross-sectional view of an antenna apparatus according to an example.

FIGS. 8A, 8B, 8C, 8D, 8E, 8F, and 8G illustrate cross-sectional views showing a manufacturing method of the antenna apparatus illustrated in FIG. 7.

FIG. 9 illustrates a cross-sectional view of an antenna apparatus according to another example.

FIG. 10 illustrates a cross-sectional view of an antenna apparatus according to another example.

FIG. 11 illustrates a cross-sectional view of an antenna apparatus according to another example.

FIG. 12 illustrates a cross-sectional view of an antenna apparatus according to another example.

FIG. 13 illustrates a cross-sectional view of an antenna apparatus according to another example.

FIG. 14 illustrates a cross-sectional view of an antenna apparatus according to another example.

FIG. 15 illustrates a schematic diagram of an electronic device including an antenna apparatus according to an example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

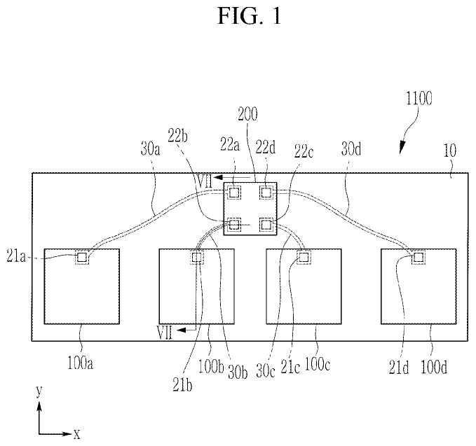

An antenna apparatus according to an example will be described with reference to FIG. 1. FIG. 1 conceptually illustrates a flat surface of an antenna apparatus according to an example.

Referring to FIG. 1, the antenna apparatus 1100 includes a plurality of antennas 100a, 100b, 100c, and 100d disposed on a first insulation layer 10, and an electronic element 200 for transferring an electrical signal to the antennas 100a, 100b, 100c, and 100d. For example, the electronic element 200 may be an integrated circuit (IC).

The first insulation layer 10 may be a copper clad laminate (CCL), but the configuration is not limited thereto. Each of the antennas 100a, 100b, 100c, and 100d may be a dielectric resonator antenna (DRA), but the configuration is not limited thereto.

The antennas 100a, 100b, 100c, and 100d may be separately disposed along a first direction x, and the electronic element 200 may be disposed to be spaced apart from the antennas 100a, 100b, 100c, and 100d along a second direction y.

A plurality of first contact holes 21a, 21b, 21c, and 21d are respectively positioned to overlap the antennas 100a, 100b, 100c, and 100d, and a plurality of second contact holes 22a, 22b, 22c, and 22d are positioned to overlap the electronic element 200. A plurality of first connection wires 30a, 30b, 30c, and 30d are disposed to overlap the first contact holes 21a, 21b, 21c, and 21d and the second contact holes 22a, 22b, 22c, and 22d.

The antennas 100a, 100b, 100c, and 100d may be electrically connected to the electronic element 200 through the first contact holes 21a, 21b, 21c, and 21d, the second holes 22a, 22b, 22c, and 22d, and the first connection wires 30a, 30b, 30c, and 30d, to receive an electrical signal from the electronic element 200.

However, either of the first contact holes 21a, 21b, 21c, and 21d and the second contact holes 22a, 22b, 22c, and 22d may be omitted.

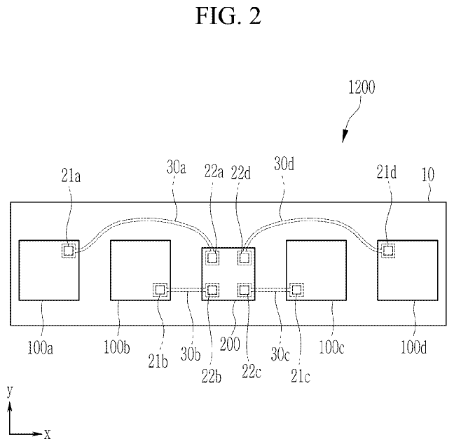

An antenna apparatus according to an example will be described with reference to FIG. 2. FIG. 2 conceptually illustrates a flat surface of an antenna apparatus according to an example.

Referring to FIG. 2, the antenna apparatus 1200 includes a plurality of antennas 100a, 100b, 100c, and 100d disposed on a first insulation layer 10, and an electronic element 200 for transferring an electrical signal to the antennas 100a, 100b, 100c, and 100d. The antennas 100a, 100b, 100c, and 100d and the electronic element 200 may be separately disposed along a first direction x, and the electronic element 200 may be disposed between the antennas 100a, 100b, 100c, and 100d.

A plurality of first contact holes 21a, 21b, 21c, and 21d are respectively positioned to overlap the antennas 100a, 100b, 100c, and 100d, and a plurality of second contact holes 22a, 22b, 22c, and 22d are positioned to overlap the electronic element 200. A plurality of first connection wires 30a, 30b, 30c, and 30d are disposed to overlap the first contact holes 21a, 21b, 21c, and 21d and the second contact holes 22a, 22b, 22c, and 22d.

The antennas 100a, 100b, 100c, and 100d may be electrically connected to the electronic element 200 through the first contact holes 21a, 21b, 21c, and 21d, the second holes 22a, 22b, 22c, and 22d, and the first connection wires 30a, 30b, 30c, and 30d, to receive an electrical signal from the electronic element 200.

However, either of the first contact holes 21a, 21b, 21c, and 21d and the second contact holes 22a, 22b, 22c, and 22d may be omitted.

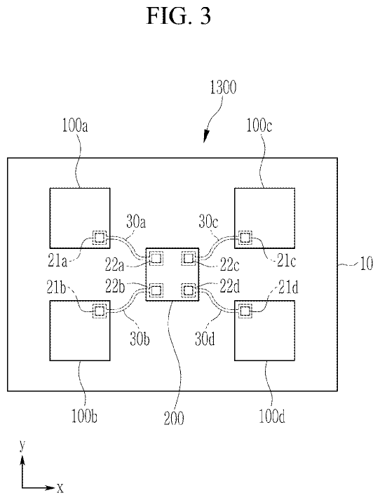

An antenna apparatus according to an example will be described with reference to FIG. 3. FIG. 3 conceptually illustrates a flat surface of an antenna apparatus according to an example.

Referring to FIG. 3, the antenna apparatus 1300 includes a plurality of antennas 100a, 100b, 100c, and 100d disposed on a first insulation layer 10, and an electronic element 200 for transferring an electrical signal to the antennas 100a, 100b, 100c, and 100d. The electronic element 200 is disposed at a central portion on a plane that is formed by a first direction x and a second direction y, and the antennas 100a, 100b, 100c, and 100d are separately disposed in vertical and horizontal directions.

A plurality of first contact holes 21a, 21b, 21c, and 21d are respectively positioned to overlap the antennas 100a, 100b, 100c, and 100d, and a plurality of second contact holes 22a, 22b, 22c, and 22d are positioned to overlap the electronic element 200. A plurality of first connection wires 30a, 30b, 30c, and 30d are disposed to overlap the first contact holes 21a, 21b, 21c, and 21d and the second contact holes 22a, 22b, 22c, and 22d.

The antennas 100a, 100b, 100c, and 100d may be electrically connected to the electronic element 200 through the first contact holes 21a, 21b, 21c, and 21d, the second holes 22a, 22b, 22c, and 22d, and the first connection wires 30a, 30b, 30c, and 30d, to receive an electrical signal from the electronic element 200.

However, either of the first contact holes 21a, 21b, 21c, and 21d and the second contact holes 22a, 22b, 22c, and 22d may be omitted.

In the examples illustrated in FIG. 1 to FIG. 3, the plurality of antennas includes four antennas, and the four antennas are described as being connected to one electronic element, but the configuration is not limited thereto, and all cases in which the plurality of antennas are connected to the electronic element are possible.

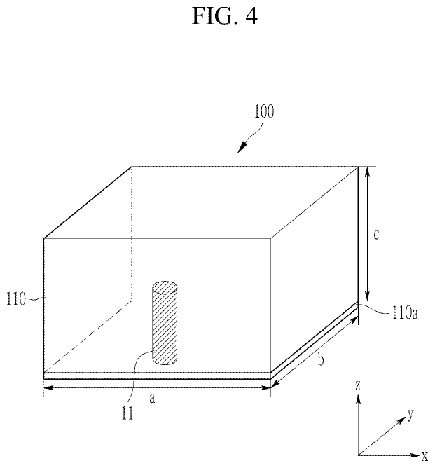

Hereinafter, a structure of an antenna according to an example will be described with FIG. 4. FIG. 4 conceptually illustrates an example of a structure of an antenna according to an example.

Referring to FIG. 4, the antenna 100 includes a dielectric layer 110 having a rectangular parallelepiped shape having a first length “a” along a first direction x, a second length “b” along a second direction y, and a third length “c” along a third direction z, and a power supply 11 for transferring an electrical signal of a predetermined value to the dielectric layer 110. A ground layer 110a may be disposed below the dielectric layer 110.

When the electrical signal is applied to the power supply 11, resonance of a certain frequency may occur inside the dielectric layer 110, and an RF signal may be transmitted and received depending on a resonance frequency of the antenna 100.

Such RF signals may include Wi-Fi (IEEE 802.11 family, etc.), WiMAX (IEEE 802.16 family, etc.), IEEE 802.20, LTE (long term evolution), Ev-DO, HSPA+, HSDPA+, HSUPA+, EDGE, GSM, GPS, GPRS, CDMA, TDMA, DECT, Bluetooth, 3G, 4G, 5G, and any other wireless and wired protocols designated thereafter, but the configuration is limited thereto.

The resonance frequency inside the dielectric layer 110 may be determined from a relative permittivity of dielectric layer 110, a value of the first length a in the first direction x of the dielectric layer 110, a value of the second length b in the second direction y, a value of the third length c in the third direction z, and an axial propagation constant that is parallel to the first direction x or the third direction z.

When the resonance frequency of the antenna 100 is constant and if the specific inductive capacity of the dielectric layer 110 is e, a size of the antenna 100 is proportional to e-½. Therefore, when the specific inductive capacity of the dielectric layer 110 is increased, the size of the antenna 100 may be reduced.

The dielectric layer 110 of the antenna 100 may have a large dielectric constant, e.g., may have a dielectric constant of 1 or more, more specifically, 10 or more.

The dielectric layer 110 may include at least one of glass, ceramic, silicone, a thermosetting resin such as an epoxy resin, a thermoplastic resin such as a polyimide, and insulating materials such as resins impregnated into core materials such as glass fibers (Glass Fiber, Glass Cloth, and Glass Fabric), and the like, with these resins.

As described above, since the dielectric layer 110 of the antenna 100 has a large dielectric constant, predetermined antenna performance may be obtained without increasing the size of the antenna 100.

According to the present example, the antenna 100, which is a dielectric resonator antenna, may not use a conductor as a radiating element, leading to no conductor loss in a high frequency region, and thus a relatively wide bandwidth and high radiation efficiency may be obtained.

The antenna described with reference to FIG. 4 is an example, and the configuration is not limited thereto, and for example, an antenna structure including a dielectric material having a large dielectric constant and using the dielectric material as a resonant medium is applicable.

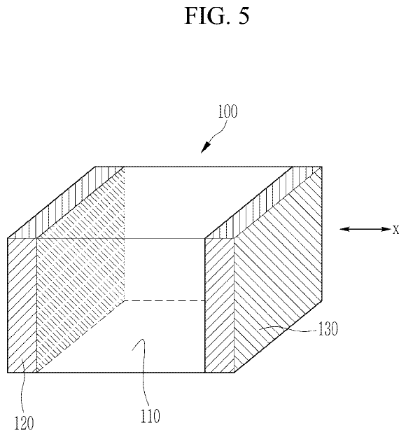

Hereinafter, a structure of an antenna according to another example will be described with FIG. 5. FIG. 5 conceptually illustrates an example of a structure of an antenna according to an example.

Referring to FIG. 5, the antenna 100 includes a first electrode 120 and a second electrode 130 facing each other with a dielectric layer 110 interposed therebetween.

The first electrode 120 and the second electrode 130 of the antenna 100 may be separately disposed to face each other along the first direction x, for example. Any one of the first electrode 120 and the second electrode 130, e.g., the first electrode 120 disposed at a left side along the first direction x, may be connected to an electronic element to receive an electrical signal, which is operated as a radiator, and the second electrode 130 disposed at a right side along the first direction x may not be connected to the electronic element, which is operated as a director of the antenna.

The antenna 100 may transmit and receive an RF signal by coupling of the first electrode 120 and the second electrode 130, and may have linearity in a direction that is parallel to the first direction x by forming a radiation pattern in the direction that is parallel to the first direction x.

A direction in which the first electrode 120 and the second electrode 130 of the antenna 100 face may be changed as necessary, and a direction in which the antenna has linearity may be changed by changing this direction.

Such RF signals may include Wi-Fi (IEEE 802.11 family, etc.), WiMAX (IEEE 802.16 family, etc.), IEEE 802.20, LTE (long term evolution), Ev-DO, HSPA+, HSDPA+, HSUPA+, EDGE, GSM, GPS, GPRS, CDMA, TDMA, DECT, Bluetooth, 3G, 4G, 5G, and any other wireless and wired protocols designated thereafter, but the configuration is limited thereto.

The dielectric layer 110 of the antenna 100 may have a large dielectric constant, e.g., may have a dielectric constant of 1 or more, more specifically, 10 or more.

The dielectric layer 110 may include at least one of glass, ceramic, silicone, a thermosetting resin such as an epoxy resin, a thermoplastic resin such as a polyimide, and insulating materials such as resins impregnated into core materials such as glass fibers (Glass Fiber, Glass Cloth, and Glass Fabric), and the like, with these resins.

As described above, since the dielectric layer 110 of the antenna 100 has a large dielectric constant, predetermined antenna performance may be obtained without increasing the size of the antenna 100.

In addition, as described above, the antenna apparatus may include a plurality of antennas, and may adjust a direction in which the first electrode 120 and the second electrode 130 of each of the antennas face each other. Accordingly, a direction in which the antenna apparatus may transmit and receive an RF signal may be varied by adjusting or varying a direction in which the antenna 100 has linearity, thereby increasing directionality of the antennas.

In the example illustrated in FIG. 5, the antenna is described as having linearity in a direction that is parallel to the first direction, but the configuration is not limited thereto, and resonance directions of the antennas may be changed depending on design of the antenna apparatus.

The antenna described with reference to FIG. 5 is an example, and the various examples are not limited thereto, and for example, an antenna structure including a dielectric material having a large dielectric constant and using the dielectric material as a resonant medium is applicable.

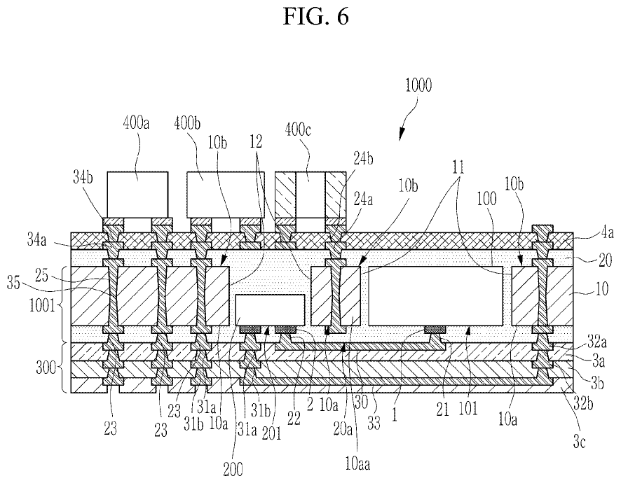

Hereinafter, an antenna apparatus according to an example will be described with reference to FIG. 6. FIG. 6 illustrates a cross-sectional view of an antenna apparatus according to an example.

Referring to FIG. 6, the antenna apparatus 1000 an antenna 100 disposed in a first cavity 11 of a first insulation layer 10, an antenna module 1001 including an electronic element 200 that is disposed in a second cavity 12 of the first insulation layer 10 to transmit an electrical signal to the antenna 100, and a connector 300 disposed below the antenna module 1001. The electronic element 200 may be an integrated circuit (IC).

A plurality of electronic components 400a, 400b, and 400c are disposed on the antenna module 1001.

Depths of the first cavity 11 and the second cavity 12 of the first insulation layer 10 may be almost the same.

The first cavity 11 and the second cavity 12 may be spaced apart from each other, and a portion of the first insulation layer 10 positioned between the first cavity 11 and the second cavity 12 may serve as a side wall 10aa that separates the antenna 100 positioned in the first cavity 11 and the electronic element positioned in the second cavity 12 from each other. A resonance frequency of the antenna 100 or the like may be prevented from being influenced by the electronic element 200 by separating the antenna 100 and the electronic element 200 through the side wall 10aa. Although not illustrated, a conductive layer may be positioned on a side surface of the side wall 10aa, and the conductive layer may serve to shield the antenna 100 and the electronic element 200 from each other. In another configuration, the side wall may be omitted.

The first insulation layer 10 has a first surface 10a and a second surface 10b positioned at opposite sides in parallel to the third direction z, e.g., at a lower side and an upper side in parallel to the third direction z, respectively, the antenna 100 has a third surface 101 positioned in a direction that faces the third direction z, i.e., at the lower side in the direction that is parallel to the direction z, like the first surface 10a of the first insulation layer 10, and similarly, the electronic element 200 has a fourth surface 201 positioned in the direction that faces the third direction z, i.e., at the lower side in the direction that is parallel to the direction z, like the first surface 10a of the first insulation layer 10.

Height of the first surface 10a of the first insulation layer 10, the third surface 101 of the antenna 100, and the fourth surface 201 of the electronic element 200 may be almost the same. Accordingly, the third surface 101 of the antenna 100 and the fourth surface 201 of the electronic element 200 are substantially coplanar with the first surface 10a of the first insulation layer 10. Herein, “height” may be a height measured in the third direction based on the second surface 10b of the first insulation layer 10, for example.

On the other hand, a height of the second surface 10b of the first insulation layer 10 may be different from that of the antenna 100 or the electronic element 200.

A filling layer 20 is filled between the first cavity 11 and the second cavity 12 of the first insulation layer 10 and between the antenna 100 and electronic element 200.

The filling layer 20 includes a portion covering the first surface 10a of the first insulation layer 10, the third surface 101 of the antenna 100, and the fourth surface 201 of the electronic element 200, i.e., a portion positioned below the first surface 10a of the first insulation layer 10, the third surface 101 of the antenna 100, and the fourth surface 201 of the electronic element 200.

The filling layer 20 has a first contact hole 21 and a second contact hole 22 positioned in a surface 20a that faces the third direction z like the first surface 10a of the first insulation layer 10. The first contact hole 21 exposes a portion of a first contact pad 1 of the antenna 100, and the second contact hole 22 exposes a portion of a second contact pad 2 of the electronic element 200.

The filling layer 20 may additionally have a plurality of third contact holes 23, and the third contact holes 23 may be positioned at positions overlapping other parts except the antenna 100 and the electronic element 200.

A first connection wire 30 is positioned below the surface 20a of the filling layer 20, and is positioned in the first contact hole 21 overlapping the first contact pad 1 of the antenna 100 and the second contact hole 22 overlapping the second contact pad 2 of the electronic element 200, thereby electrically connecting the antenna 100 and the electronic element 200. The first contact pad 1 of the antenna 100 and the second contact pad 2 of the electronic element 200 exposed through the first contact hole 21 and the second contact hole 22 of the filling layer 20 may contact the first connection wire 30, whereby the antenna 100 and the electronic element 200 may be electrically connected to each other through the first contact hole 21 and the second contact hole 22 of the filling layer 20, and the first connection wire 30.

The connector 300 is disposed at a portion that overlappingly covers the first connection wire 30 and the filling layer 20 in the third direction z, i.e., below the first connection wire 30 and the filling layer 20. The connector 300 may include a second insulation layer 3a, a third insulation layer 3b, and a fourth insulation layer 3c, a plurality of contact holes 31a and 31b, a plurality of contact members 32a and 32b overlapping the contact holes 31a and 31b, and a second connection wire 33 for connecting the electronic element and an external component through contact members 32a and 32b. Although not illustrated, the antenna apparatus 1000 may be disposed to contact the connector 300 along the third direction z to further include an additional component connected to the second connection wire 33 or a ground plane of the connector 300.

The filling layer 20 has a plurality of contact holes 24a formed in a surface facing a direction that is opposite to the third direction z, like the second surface 10b of the first insulation layer 10, that is, positioned above the first insulation layer 10.

A fourth insulation layer 4a is disposed on the third insulation layer 20. The fourth insulation layer 4a has a plurality of contact holes 24b.

A plurality of electronic components 400a, 400b, and 400c are disposed to overlap the contact holes 24a of the filling layer 20 and the contact holes 24b of the fourth insulation layer 4a on the fourth insulation layer 4a. A plurality of contact members 34a are disposed in the contact holes 24a of the filling layer 20, and a plurality of contact members 34b are disposed in the contact holes 24b of the fourth insulation layer 4a.

A plurality of connection vias 25 are formed in the first insulation layer 10 so as to overlap the contact holes 24a of the filling layer 20 and the contact holes 24b of the fourth insulation layer 4a, and the electronic components 400a, 400b, and 400c and the connector 300 may be connected to each other through a connection member 35 disposed in the connection vias 25. Accordingly, the electronic components 400a, 400b, and 400c may be connected to an additional electronic component positioned below the connector 300 through the connector 300, or may be connected to the antenna 100 or the electronic element 200.

Although not illustrated, a plurality of insulation layers may be further disposed between the filling layer 20 and the electronic components 400a, 400b, and 400c, and positions of the electronic components 400a, 400b, and 400c, positions of the contact holes, and a thickness and a number of the insulation layers may be changed depending on designs thereof.

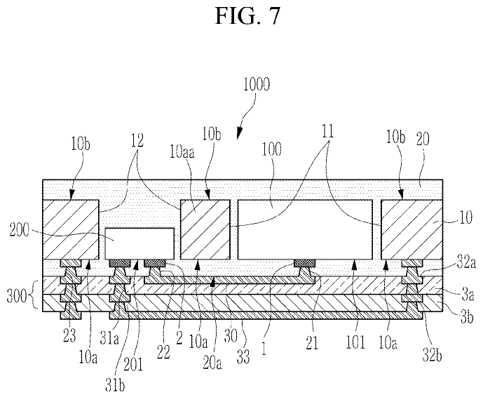

Hereinafter, a portion of an antenna apparatus according to an example will described with reference to FIG. 7. FIG. 7 illustrates a cross-sectional view of an antenna apparatus according to an example, showing the antenna apparatus of FIG. 1 taken along a line VII-VII of FIG. 1.

Referring to FIG. 7, the antenna apparatus 1000 includes an antenna 100 disposed in a first cavity 11 of a first insulation layer 10, and an electronic element 200 that is disposed in a second cavity 12 of the first insulation layer 10 to transmit an electrical signal to the antenna 100. The electronic element 200 may be an integrated circuit (IC).

The first insulation layer 10 may be a copper clad laminate (CCL). Depths of the first cavity 11 and the second cavity 12 of the first insulation layer 10 may be almost the same.

The first cavity 11 and the second cavity 12 may be spaced apart from each other, and a portion of the first insulation layer 10 positioned between the first cavity 11 and the second cavity 12 may serve as a side wall 10aa that separates the antenna 100 disposed in the first cavity 11 and the electronic element 200 disposed in the second cavity 12 from each other. A resonance frequency of the antenna 100 or the like may be prevented from being influenced by the electronic element 200 by separating the antenna 100 and the electronic element 200 through the side wall 10aa. Although not illustrated, a conductive layer may be positioned on a side surface of the side wall 10aa, and the conductive layer may serve to shield the antenna 100 and the electronic element 200 from each other.

The first insulation layer 10 has a first surface 10a and a second surface 10b positioned at opposite sides in parallel to the third direction z, the antenna 100 has a third surface 101 positioned in a direction that faces the third direction z like the first surface 10a of the first insulation layer 10, and similarly, the electronic element 200 has a fourth surface 201 positioned in the direction that faces the third direction z like the first surface 10a of the first insulation layer 10.

Heights of the first surface 10a of the first insulation layer 10, the third surface 101 of the antenna 100, and the fourth surface 201 of the electronic element 200 may be almost the same. Accordingly, the third surface 101 of the antenna 100 and the fourth surface 201 of the electronic element 200 are substantially coplanar with the first surface 10a of the first insulation layer 10. Herein, “height” may be a height measured in the third direction based on the second surface 10b of the first insulation layer 10, for example.

On the other hand, a height of the second surface 10b of the first insulation layer 10 may be different from that of the antenna 100 or the electronic element 200.

A filling layer 20 is filled between the first cavity 11 and the second cavity 12 of the first insulation layer 10 and between the antenna 100 and electronic element 200. The filling layer 20 may include at least one of insulating materials including inorganic fillers and insulating resins, e.g., thermosetting resins such as epoxy resins, thermoplastic resins such as polyimide, or these resins containing reinforcing materials such as inorganic fillers, specifically, materials in which insulating resins such as ABF, FR-4, BT resin, or thermosetting resins or thermoplastic resins are impregnated into core materials such as inorganic fillers and/or glass fibers (Glass Fiber, Glass Cloth, and Glass Fabric).

The filling layer 20 includes a portion covering the first surface 10a of the first insulation layer 10, the third surface 101 of the antenna 100, and the fourth surface 201 of the electronic element 200, i.e., a portion positioned below the first surface 10a of the first insulation layer 10, the third surface 101 of the antenna 100, and the fourth surface 201 of the electronic element 200.

The filling layer 20 has a first contact hole 21 and a second contact hole 22 positioned in a surface 20a that faces the third direction z like the first surface 10a of the first insulation layer 10. The first contact hole 21 exposes a portion of a first contact pad 1 of the antenna 100, and the second contact hole 22 exposes a portion of a second contact pad 2 of the electronic element 200.

The filling layer 20 may additionally have a plurality of third contact holes 23, and the third contact holes 23 may be positioned at positions overlapping other parts except the antenna 100 and the electronic element 200.

A first connection wire 30 is positioned in a surface 20a of the filling layer 20, and is positioned in the first contact hole 21 overlapping the first contact pad 1 of the antenna 100 and the second contact hole 22 overlapping the second contact pad 2 of the electronic element 200, thereby electrically connecting the antenna 100 and the electronic element 200. The first contact pad 1 of the antenna 100 and the second contact pad 2 of the electronic element 200 exposed through the first contact hole 21 and the second contact hole 22 of the filling layer 20 may contact the first connection wire 30, whereby the antenna 100 and the electronic element 200 may be electrically connected to each other through the first contact hole 21 and the second contact hole 22 of the filling layer 20, and the first connection wire 30.

As described above, a height of the first surface 10a of the first insulation layer 10 adjacent to the first connection wire 30, a height of the third surface 101 of the antenna 100, and a height of the fourth surface 201 of the electronic element 200 are almost the same, and the surfaces 10a, 101, and 201 are almost coplanar, and thus a first depth of the third surface 101 of the antenna 100 and a second depth of the fourth surface 201 of the electronic element 200 are almost the same based on the surface 20a of the filling layer 20 where the first connection wire 30 is positioned. Accordingly, the depths of the first contact hole 21 and the second contact hole 22 formed in the filling layer 20 may be almost the same. Therefore, when the first connection wire 30 is formed in the first contact hole 21 and the second contact hole 22, a problem in which a contact force of the connection wires is weakened, such as some of the connection wires being short-circuited and some not being short-circuited, due to a difference in depths of the contact holes, may not occur. Therefore, reliability of electrical connection between the antenna 100 and the electronic element 200 may be improved. In addition, the antenna 100 and the electronic element 200 may be connected by connection wires disposed on the surface of the filling layer 20, which is the connection wire closest thereto, thereby simplifying a connection structure and shortening the length of the connection wires 30, and thus a volume of the antenna apparatus may not be increased, reliability of the electrical connection between the antenna 100 and the electronic element 200 may be increased, and a signal delay due to resistance of the connection wires 30 may be prevented, compared to the case of connecting them through a plurality of wires or the like disposed in a plurality of different insulation layers.

A connector 300 is disposed at a portion that overlappingly covers the first connection wire 30 and the filling layer 20 in the third direction z, i.e., below the first connection wire 30 and the filling layer 20. The connector 300 may include a second insulation layer 3a and a third insulation layer 3b, a plurality of contact holes 31a and 31b, a plurality of contact members (ohmic contacts) 32a and 32b overlapping the contact holes 31a and 31b, and a second connection wire 33 for connecting the electronic element and an external component through contact members 32a and 32b. Although not illustrated, the antenna apparatus 1000 may be disposed to contact the connector 300 along the third direction z to further include an additional component connected to the connection wire 33 or a ground plane of the connector 300. For example, an additional component may include at least one of an inductor, a capacitor, and a resistor.

The antenna apparatus 1000 may include the antenna 100 and the electronic element 200 disposed in the first cavity 11 and the second cavity 12 of the first insulation layer 10 to be spaced apart from each other by the side wall 10aa, and the antenna 100 and the electronic element 200 may be disposed in the first contact hole 21 and the second contact hole 22 formed in the filling layer 20 and a surface of the filling layer 20 to be electrically connected through the first connection wire 30 positioned in the first contact hole 21 and the second contact hole 22.

As such, the antenna 100 and the electronic element 200 of the antenna apparatus 1000 are disposed in the first cavity 11 and the second cavity 12 of the first insulation layer 10, thereby reducing a volume occupied by the antenna apparatus 1000 compared with a case where the antenna 100 and the electronic element 200 are disposed to vertically overlap each other along the third direction z. In addition, the antenna 100 and the electronic element 200 of the antenna apparatus 1000 may be electrically connected to each other through the first contact hole 21 and second contact hole 22 and the first connection wire 30 without using an additional electrical connection member, such as a solder ball, and thus it is possible to prevent the characteristic of the antenna from being deteriorated or the antenna loss caused by the electrical connection member.

In addition, the third surface 101 of the antenna 100 and the fourth surface 201 of the electronic element 200 adjacent to the first connection wire 30 may be substantially coplanar with the first surface 10a of the first insulation layer 10, so that there is little difference in spacing between the first connection wires 30 and the antenna 100 and the electronic element 200. Therefore, when the first connection wires 30 and the antenna 100 and the electronic element 200 are connected, a problem such as a short circuit does not occur, and accordingly, reliability of the electrical connection between the antenna 100 and the electronic element 200 may increase.

In addition, the antenna 100 and the electronic element 200 may be connected by connection wires disposed on the surface of the filling layer 20, which is the connection wire closest thereto, thereby simplifying a connection structure and shortening the length of the connection wires 30, and thus a volume of the antenna apparatus may not be increased, reliability of the electrical connection between the antenna 100 and the electronic element 200 may be increased, and a signal delay due to resistance of the connection wires 30 may be prevented, compared to the case of connecting them through a plurality of wires or the like disposed in a plurality of different insulation layers.

In addition, the antenna 100 and the electronic element 200 of the antenna apparatus 1000 may be disposed in the first cavity 11 and the second cavity 12 of the first insulation layer 10, they may be protected by the filling layer 20, and accordingly, a stacking process of an additional protective layer such as an epoxy mold compound (EMC) for protecting the antenna 100 and the electronic element 200 may be omitted.

According to the example illustrated in FIG. 7, one antenna and an electronic element are described as an example, but the configuration is not limited thereto, and as described above, it is applicable to all antenna apparatuses including a plurality of antennas.

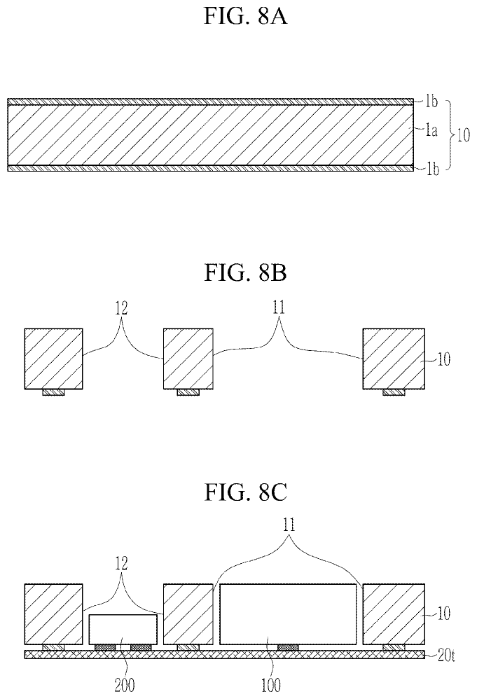

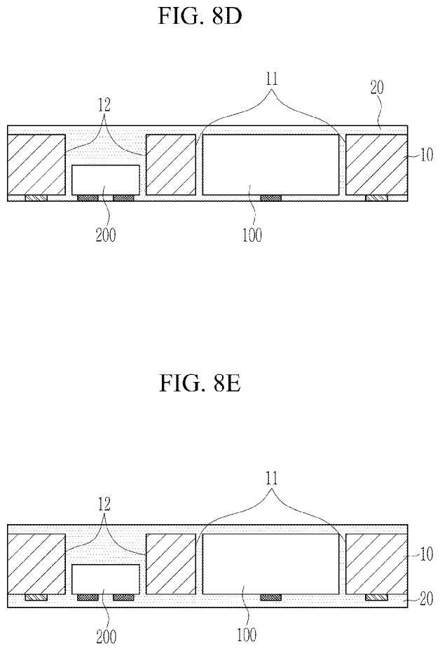

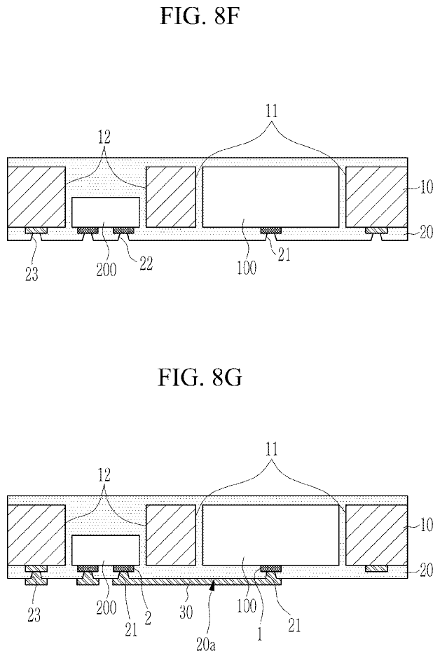

Hereinafter, a manufacturing method of an antenna apparatus according to an example will be described with reference to FIG. 8A to FIG. 8G together with FIG. 7. FIG. 8A to FIG. 8G illustrate cross-sectional views showing a manufacturing method of an antenna apparatus illustrated in FIG. 7.

As illustrated in FIG. 8A, a first insulation layer 10 is prepared. The first insulation layer 10 may be a copper foil laminate. The first insulation layer 10 may include a first layer 1a including an insulating material and a second layer 1b which is a copper foil layer disposed on opposite sides of the first layer 1a.

As illustrated in FIG. 8B, a first cavity 11 and a second cavity 12 are formed in the first insulation layer 10. In this case, at least a portion of the second layer 1b of the first insulation layer 10 may be removed.

Referring to FIG. 8C, the antenna 100 is disposed in the first cavity 11 and the electronic element 200 is disposed in the second cavity 12, after an adhesive tape 20t is disposed at a side of a first surface 10a of the first insulation layer 10 having the first cavity 11 and the second cavity 12. In this case, since the antenna 100 and the electronic element 200 are attached to the adhesive tape 20t disposed below the first insulation layer 10, heights of a third surface 101 of the antenna 100 and a fourth surface 201 of the electronic element 200 may be substantially the same as that of the first surface 10a of the first insulation layer 10.

As illustrated in FIG. 8D, a filling layer 20 is filled between the first cavity 11 and the second cavity 12 of the first insulation layer 10 and between the antenna 100 and the electronic element 200, and then the adhesive tape 20t is removed. For example, the filling layer 20 may be filled by a lamination method.

As illustrated in FIG. 8E, the filling layer 20 is formed in the first surface 10a side of the first insulation layer 10 from which the adhesive tape 20t is removed, that is, below the first insulation layer 10. In this case, the filling layer 20 may be filled by a lamination method.

As illustrated in FIG. 8F and 8G, the first contact hole 21 exposing a portion of the first contact pad 1 of the antenna 100 and the second contact hole 22 exposing a portion of the second contact pad 2 of the electronic element 200 are formed by etching the surface 20a of the filling layer 20 disposed at a side of the first surface 10a of the first insulation layer 10. In this case, a plurality of third contact holes 23 may be additionally formed.

As illustrated in FIG. 8G, the connection wires 30 disposed in the first contact hole 21 overlapping the first contact pad 1 of the antenna 100 and the second contact hole 22 overlapping the second contact pad 2 of the electronic element 200 are formed on the surface 20a of the filling layer 20, that is, below the filling layer 20. As such, the first contact pad 1 of the antenna 100 and the second contact pad 2 of the electronic element 200 exposed through the first contact hole 21 and the second contact hole 22 of the filling layer 20 contact the first connection wire 30, whereby the antenna 100 and the electronic element 200 are electrically connected to each other through the first contact hole 21 and the second contact hole 22 of the filling layer 20 and the first connection wire 30.

Next, the antenna apparatus 1000 illustrated in FIG. 7 may be formed by attaching the connector 300 at a position overlapping the first connection wires 30 and the filling layer 20. In addition, an additional component may be further disposed to contact the connector 300.

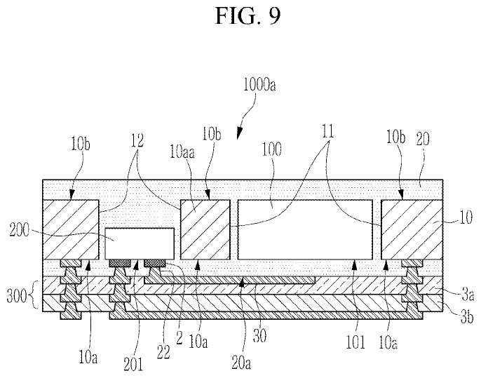

Hereinafter, an antenna apparatus according to another example will be described with reference to FIG. 9. FIG. 9 illustrates a cross-sectional view of an antenna apparatus according to another example.

Referring to FIG. 9, the antenna apparatus 1000a has some similar features to the antenna apparatus 1000 described with reference to FIG. 7. A detailed description of same constituent elements will be omitted.

As illustrated in FIG. 9, the antenna apparatus 1000a includes an antenna 100 and an electronic element 200 positioned in the first cavity 11 and the second cavity 12 of the first insulation layer 10 to be spaced apart from each other by an insulating side wall 10aa. The first insulation layer 10 has a first surface 10a and a second surface 10b positioned at opposite sides in parallel to the third direction z, the antenna 100 has a third surface 101 positioned in a direction that faces the third direction z like the first surface 10a of the first insulation layer 101, and similarly, the electronic element 200 has a fourth surface 201 positioned in the direction that faces the third direction z like the first surface 10a of the first insulation layer 101.

A height of the first surface 10a of the first insulation layer 10 is almost the same as that of the third surface 101 of the antenna 100 and that of the fourth surface 201 of the electronic element 200, and thus the surfaces 10a, 101, and 201 may be substantially coplanar.

A filling layer 20 is filled between the first cavity 11 and the second cavity 12 of the first insulation layer 10 and between the antenna 100 and electronic element 200.

The filling layer 20 has a second contact hole 22, which is formed in the surface 20a facing the third direction z like the first surface 10a of the first insulation layer 10 to expose a portion of the second contact pad 2 of the electronic element 200.

The first connection wire 30 is disposed on the surface 20a of the filling layer 20, and the first connection wire 30 is disposed in the second contact hole 22 overlapping the second contact pad 2 of the electronic element 200 to be connected to the electronic element 200 to overlap the antenna 100. As such, the first connection wire 30 connected and fed to the electronic element 200 may overlap the antenna 100 with the filling layer 20 disposed therebetween to achieve coupling, thereby providing power to the antenna 100. This feeding method is referred to as coupling feeding.

The connector 300 is disposed below the first connection wire 30 and the filling layer 20 to overlap the first connection wire 30 and the filling layer 20 along the third direction z.

The antenna apparatus 1000a may include the antenna 100 and the electronic element 200 disposed in the first cavity 11 and the second cavity 12 of the first insulation layer 10 to be spaced apart from each other by the side wall 10aa, and the antenna 100 may be electrically connected to the electronic element 200 by coupling with the first connection wire 30 connected to the electronic element 200 through the second contact hole 22 positioned in a surface of the filling layer and formed in the filling layer 20.

As such, the antenna 100 and the electronic element 200 of the antenna apparatus 1000a may be disposed in the first cavity 11 and the second cavity 12 of the first insulation layer 10, thereby reducing a volume occupied by the antenna apparatus 1000a compared with a case where the antenna 100 and the electronic element 200 are disposed to vertically overlap each other along the third direction z. In addition, the antenna 100 and the electronic element 200 may be electrically connected to each other without using an additional electrical connection member, such as a solder ball, and thus it is possible to prevent the characteristic of the antenna from being deteriorated or the antenna loss caused by the electrical connection member.

In addition, the antenna 100 and the electronic element 200 of the antenna apparatus 1000a may be disposed in the first cavity 11 and the second cavity 12 of the first insulation layer 10, they may be protected by the filling layer 20, and accordingly, a forming process of an additional protective layer for protecting the antenna 100 and the electronic element 200 may be omitted.

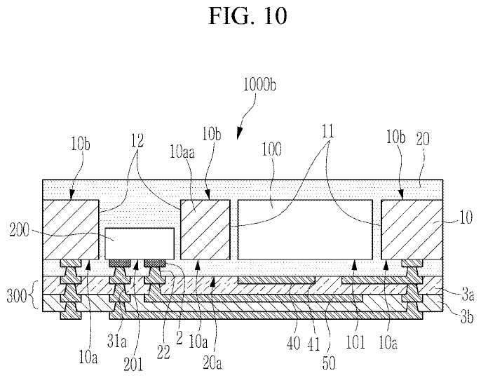

Hereinafter, an antenna apparatus according to another example will be described with reference to FIG. 10. FIG. 10 illustrates a cross-sectional view of an antenna apparatus according to another example.

Referring to FIG. 10, the antenna apparatus 1000b has some similar features to the antenna apparatus 1000 described above with reference to FIG. 7. A detailed description of same constituent elements will be omitted.

As illustrated in FIG. 10, the antenna apparatus 1000b includes an antenna 100 and an electronic element 200 positioned in the first cavity 11 and the second cavity 12 of the first insulation layer 10 to be spaced apart from each other by an insulating side wall 10aa. The first insulation layer 10 has a first surface 10a and a second surface 10b positioned at opposite sides in parallel to the third direction z, the antenna 100 has a third surface 101 positioned in a direction that faces the third direction z like the first surface 10a of the first insulation layer 10, and similarly, the electronic element 200 has a fourth surface 201 positioned in the direction that faces the third direction z like the first surface 10a of the first insulation layer 10.

A height of the first surface 10a of the first insulation layer 10 is almost the same as that of the third surface 101 of the antenna 100 and that of the fourth surface 201 of the electronic element 200, and thus the surfaces 10a, 101, and 201 may be substantially coplanar.

A filling layer 20 is filled between the first cavity 11 and the second cavity 12 of the first insulation layer 10 and between the antenna 100 and electronic element 200.

The filling layer 20 may have a second contact hole 22, which is formed in the surface 20a facing the third direction z like the first surface 10a of the first insulation layer 10 to expose a portion of the second contact pad 2 of the electronic element 200.

A connecting layer 40 having a slot 41 is disposed on the surface 20a of the filling layer 20.

The connector 300 is disposed in a surface of the connecting layer 40, i.e., below the connecting layer 40, and a power supply wire 50 that is connected to the electronic element 200 through the contact hole 31a that is aligned with the second contact hole 22 is disposed between the second insulation layer 3a and the third insulation layer 3b of the connector 300.

When power is supplied from the electronic element 200 through the power supply wire 50, the connecting layer 40 having the slot 41 is coupled to the power supply wire 50 to receive an electromagnetic field to be coupled with the antenna 100, thereby supplying power to the antenna. This feeding method is referred to as slot feeding. A size and a shape of the slot 41 of the connecting layer 40 may be changed depending on a resonance frequency of the antenna.

As such, the antenna 100 and the electronic element 200 of the antenna apparatus 1000b may be disposed in the first cavity 11 and the second cavity 12 of the first insulation layer 10, thereby reducing a volume occupied by the antenna apparatus 1000b compared with a case where the antenna 100 and the electronic element 200 are disposed to vertically overlap each other along the third direction z. In addition, the antenna 100 and the electronic element 200 may be electrically connected to each other without using an additional electrical connection member, such as a solder ball, and thus it is possible to prevent the characteristic of the antenna from being deteriorated or the antenna loss caused by the electrical connection member.

In addition, the antenna 100 and the electronic element 200 of the antenna apparatus 1000b may be disposed in the first cavity 11 and the second cavity 12 of the first insulation layer 10, they may be protected by the filling layer 20, and accordingly, a forming process of an additional protective layer for protecting the antenna 100 and the electronic element 200 may be omitted.

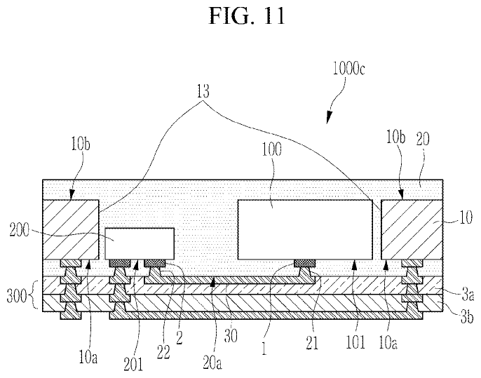

Hereinafter, an antenna apparatus according to another example will be described with reference to FIG. 11. FIG. 11 illustrates a cross-sectional view of an antenna apparatus according to another example.

Referring to FIG. 11, the antenna apparatus 1000c has some similar features to the antenna apparatus 1000 illustrated in FIG. 7. A detailed description of same constituent elements will be omitted.

As illustrated in FIG. 11, the antenna apparatus 1000c has no side wall between the antenna 100 and the electronic element 200, unlike the antenna apparatus 1000 according to the example shown in FIG. 7.

The antenna apparatus 1000c includes the antenna 100 and the electronic element 200 disposed in the cavity 13 of the first insulation layer 10. The first insulation layer 10 has a first surface 10a and a second surface 10b positioned at opposite sides in parallel to the third direction z, the antenna 100 has a third surface 101 positioned in a direction that faces the third direction z like the first surface 10a of the first insulation layer 10, and similarly, the electronic element 200 has a fourth surface 201 positioned in the direction that faces the third direction z like the first surface 10a of the first insulation layer 10.

A height of the first surface 10a of the first insulation layer 10 is almost the same as that of the third surface 101 of the antenna 100 and that of the fourth surface 201 of the electronic element 200, and thus the surfaces 10a, 101, and 201 may be substantially coplanar.

A filling layer 20 is filled between the cavity 13 of the first insulation layer 10 and the antenna 100 and the electronic element 200.

The filling layer 20 has a first contact hole 21 and a second contact hole 22 positioned in a surface 20a that faces the third direction z like the first surface 10a of the first insulation layer 10. The first contact hole 21 exposes a portion of a first contact pad 1 of the antenna 100, and the second contact hole 22 exposes a portion of a second contact pad 2 of the electronic element 200.

A first connection wire 30 is positioned in a surface 20a of the filling layer 20, and is positioned in the first contact hole 21 overlapping the first contact pad 1 of the antenna 100 and the second contact hole 22 overlapping the second contact pad 2 of the electronic element 200, thereby electrically connecting the antenna 100 and the electronic element 200.

The connector 300 is disposed below the first connecting wire 30 and the filling layer 20 to overlap the first connecting wire 30 and the filling layer 20 along the third direction z.

The antenna apparatus 1000c may include the antenna 100 and the electronic element 200 disposed in the cavity 13 of the first insulation layer 10, and the antenna 100 may be electrically connected to the electronic element 200 by coupling with the first connection wire 30 connected to the electronic element 200 through the second contact hole 22 positioned in a surface of the filling layer and formed in the filling layer 20.

As such, the antenna 100 and the electronic element 200 of the antenna apparatus 1000c may be disposed in the cavity 13 of the first insulation layer 10, thereby reducing a volume occupied by the antenna apparatus 1000c compared with a case where the antenna 100 and the electronic element 200 are disposed to vertically overlap each other along the third direction z. In addition, the antenna 100 and the electronic element 200 may be electrically connected to each other without using an additional electrical connection member, such as a solder ball, and thus it is possible to prevent the characteristic of the antenna from being deteriorated or the antenna loss caused by the electrical connection member.

In addition, the antenna 100 and the electronic element 200 of the antenna apparatus 1000c may be disposed in the cavity 13 of the first insulation layer 10, they may be protected by the filling layer 20, and accordingly, a forming process of an additional protective layer for protecting the antenna 100 and the electronic element 200 may be omitted.

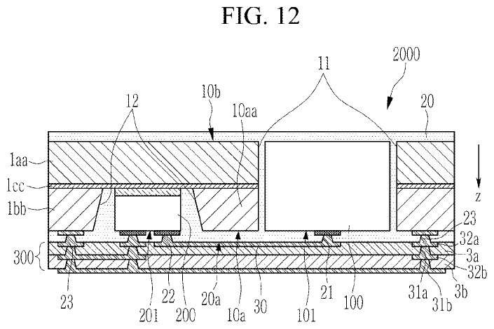

Hereinafter, an antenna apparatus according to another example will be described with reference to FIG. 12. FIG. 12 illustrates a cross-sectional view of an antenna apparatus according to another example.

Referring to FIG. 12, the antenna apparatus 2000 has some similar features to the antenna apparatus 1000 illustrated in FIG. 7. A detailed description of same constituent elements will be omitted.

As illustrated in FIG. 12, the antenna apparatus 2000 includes an antenna 100 disposed in a first cavity 11 of a first insulation layer 10, and an electronic element 200 that is disposed in a second cavity 12 of the first insulation layer 10.

In accordance with the antenna apparatus 2000, unlike the antenna apparatus 1000 illustrated in FIG. 7, the first insulation layer 10 may include two sublayers 1aa and 1bb and an intermediate layer 1cc disposed between the two sublayers 1aa and 1bb. The two sublayers 1aa and 1bb and the intermediate layer 1cc may include an insulating material, and the intermediate layer 1cc may have adherence.

The first cavity 11 of the first insulation layer 10 is formed in the two sublayers 1aa and 1bb and the intermediate layer 1cc, and the second cavity 12 of the first insulation layer 10 may be formed on the first sublayer 1aa of the two sublayers 1aa and 1bb of the first insulation layer 10. A thickness of the first sublayer 1aa may be substantially the same as that of the electronic element 200.

The first cavity 11 and the second cavity 12 may be spaced apart from each other, and a portion of the first insulation layer 10 positioned between the first cavity 11 and the second cavity 12 may serve as a side wall 10aa that separates the antenna 100 disposed in the first cavity 11 and the electronic element 200 disposed in the second cavity 12 from each other. Although not illustrated, a conductive layer may be positioned on a side surface of the side wall 10aa, and the conductive layer may serve to shield the antenna 100 and the electronic element 200 from each other. The side wall may be omitted.

The first insulation layer 10 has a first surface 10a and a second surface 10b positioned at opposite sides in parallel to the third direction z, the antenna 100 has a third surface 101 positioned in a direction that faces the third direction z like the first surface 10a of the first insulation layer 10, and similarly, the electronic element 200 has a fourth surface 201 positioned in the direction that faces the third direction z like the first surface 10a of the first insulation layer 10.

A height of the first surface 10a of the first insulation layer 10 is almost the same as that of the third surface 101 of the antenna 100 and that of the fourth surface 201 of the electronic element 200, and thus the surfaces 10a, 101, and 201 may be substantially coplanar.

A filling layer 20 is filled between the first cavity 11 and the second cavity 12 of the first insulation layer 10 and the antenna 100 and electronic element 200, and has a portion covering the first surface 10a of the first insulation layer 10, the third surface 101 of the antenna 100, and the fourth surface 201 of the electronic element 200.

The filling layer 20 has a first contact hole 21 and a second contact hole 22 positioned in a surface 20a that faces the third direction z like the first surface 10a of the first insulation layer 10. The first contact hole 21 exposes a portion of a first contact pad 1 of the antenna 100, and the second contact hole 220 exposes a portion of a second contact pad 2 of the electronic element 200. The filling layer 20 may additionally have a plurality of third contact holes 23.

A first connection wire 30 is positioned in a surface 20a of the filling layer 20, and is positioned in the first contact hole 21 overlapping the first contact pad 1 of the antenna 100 and the second contact hole 22 overlapping the second contact pad 2 of the electronic element 200, thereby electrically connecting the antenna 100 and the electronic element 200.

A connector 300 is disposed at a portion that overlappingly covers the first connection wire 30 and the filling layer 20 in the third direction z, i.e., below the first connection wire 30 and the filling layer 20. The connector 300 may include a second insulation layer 3a and a third insulation layer 3b, a plurality of contact holes 31a and 31b, and a plurality of contact members 32a and 32b overlapping the contact holes 31a and 31b. Although not illustrated, the antenna apparatus 2000 may further include an additional component contacting the connector 300 along the third direction z. For example, an additional component may include at least one of an inductor, a capacitor, and a resistor.

The antenna 100 and the electronic element 200 of the antenna apparatus 2000 may be electrically connected to the first contact hole 21 and the second contact hole 22 formed in the filling layer 20 through the first connection wire 30 disposed on the surface of the filling layer 20 and in the first contact hole 21 and the second contact hole 22.

As such, the antenna 100 and the electronic element 200 of the antenna apparatus 2000 are disposed in the first cavity 11 and the second cavity 12 of the first insulation layer 10, thereby reducing a volume occupied by the antenna apparatus 2000 compared with a case where the antenna 100 and the electronic element 200 are disposed to vertically overlap each other along the third direction z. In addition, the antenna 100 and the electronic element 200 of the antenna apparatus 2000 may be electrically connected to each other through the first contact hole 21 and the second contact hole 22 and the first connection wire 30 without using an additional electrical connection member, such as a solder ball, and thus it is possible to prevent the characteristic of the antenna from being deteriorated or the antenna loss caused by the electrical connection member.

In addition, the third surface 101 of the antenna 100 and the fourth surface 201 of the electronic element 200 adjacent to the first connection wire 30 may be substantially coplanar with the first surface 10a of the first insulation layer 10, so that there is little difference in spacing between the first connection wires 30 and the antenna 100 and the electronic element 200. Therefore, when the first connection wire 30 is connected to the antenna 100 and the electronic element 200, a problem such as a short circuit does not occur, and accordingly, reliability of the electrical connection between the antenna 100 and the electronic element 200 may increase.

In addition, the antenna 100 and the electronic element 200 may be connected by connection wires disposed on the surface of the filling layer 20 closest thereto, thereby simplifying a connection structure and shortening the length of the first connection wires 30, and thus a volume of the antenna apparatus may not be increased, reliability of the electrical connection between the antenna 100 and the electronic element 200 may be increased, and a signal delay due to resistance of the first connection wires 30 may be prevented, compared to the case of connecting them through a plurality of wires or the like disposed in a plurality of different insulation layers.

In addition, the antenna 100 and the electronic element 200 of the antenna apparatus 2000 may be disposed in the first cavity 11 and the second cavity 12 of the first insulation layer 10, they may be protected by the filling layer 20, and accordingly, a forming process of an additional protective layer for protecting the antenna 100 and the electronic element 200 may be omitted.

According to the example illustrated in FIG. 12, one antenna and an electronic element are described as an example, but the configuration is not limited thereto, and as described above, it is applicable to all antenna apparatuses including a plurality of antennas and an electronic element that is connected thereto to transmit electric signals to the antennas.

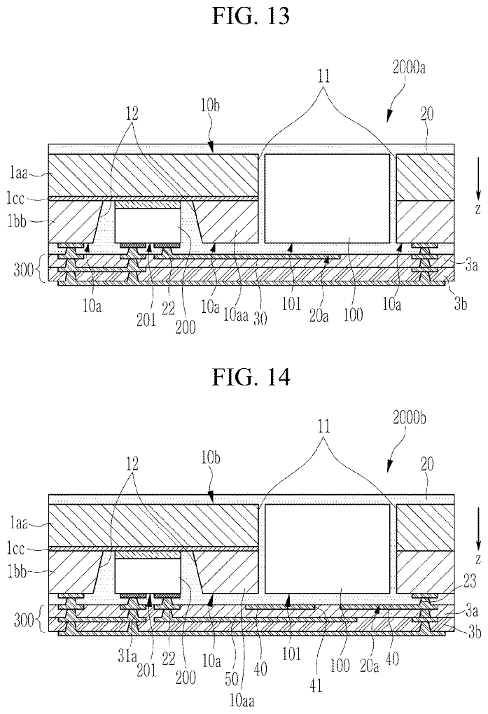

Hereinafter, an antenna apparatus according to another example will be described with reference to FIG. 13. FIG. 13 illustrates a cross-sectional view of an antenna apparatus according to another example.

Referring to FIG. 13, the antenna apparatus 2000a has some similar features to the antenna apparatus 2000 described with reference to FIG. 12. A detailed description of same constituent elements will be omitted.

As illustrated in FIG. 13, the antenna apparatus 2000a includes an antenna 100 and an electronic element 200 positioned in the first cavity 11 and the second cavity 12 of the first insulation layer 10 to be spaced apart from each other by an insulating side wall 10aa. The first insulation layer 10 has a first surface 10a and a second surface 10b positioned at opposite sides in parallel to the third direction z, the antenna 100 has a third surface 101 positioned in a direction that faces the third direction z like the first surface 10a of the first insulation layer 10, and similarly, the electronic element 200 has a fourth surface 201 positioned in the direction that faces the third direction z like the first surface 10a of the first insulation layer 10.

A height of the first surface 10a of the first insulation layer 10 is almost the same as that of the third surface 101 of the antenna 100 and that of the fourth surface 201 of the electronic element 200, and thus the surfaces 10a, 101, and 201 may be substantially coplanar.

A filling layer 20 is filled between the first cavity 11 and the second cavity 12 of the first insulation layer 10 and between the antenna 100 and electronic element 200.

The filling layer 20 has a second contact hole 22, which is formed in the surface 20a facing the third direction z like the first surface 10a of the first insulation layer 10 to expose a portion of the second contact pad 2 of the electronic element 200.

The first connecting wire 30 is disposed on the surface 20a of the filling layer 20, and the first connecting wire 30 is disposed in the second contact hole 22 overlapping the second contact pad 2 of the electronic element 200 to be connected to the electronic element 200 to overlap the antenna 100. As such, the first connecting wire 30 connected and fed to the electronic element 200 may overlap the antenna 100 with the filling layer 20 disposed therebetween to achieve coupling, thereby providing power to the antenna 100. This feeding method is referred to as coupling feeding.

The connector 300 is disposed below the first connecting wire 30 and the filling layer 20 to overlap the first connection wire 30 and the filling layer 20 along the third direction z.

The antenna apparatus 2000a may include the antenna 100 and the electronic element 200 disposed in the first cavity 11 and the second cavity 12 of the first insulation layer 10 to be spaced apart from each other by the side wall 10aa, and the antenna 100 may be electrically connected to the electronic element 200 by coupling with the first connection wire 30 connected to the electronic element 200 through the second contact hole 22 positioned in a surface of the filling layer and formed in the filling layer 20.

As such, the antenna 100 and the electronic element 200 of the antenna apparatus 2000a are disposed in the first cavity 11 and the second cavity 12 of the first insulation layer 10, thereby reducing a volume occupied by the antenna apparatus 2000a compared with a case where the antenna 100 and the electronic element 200 are disposed to vertically overlap each other along the third direction z. In addition, the antenna 100 and the electronic element 200 may be electrically connected to each other without using an additional electrical connection member, such as a solder ball, and thus it is possible to prevent the characteristic of the antenna from being deteriorated or the antenna loss caused by the electrical connection member.

In addition, the antenna 100 and the electronic element 200 of the antenna apparatus 2000a may be disposed in the first cavity 11 and the second cavity 12 of the first insulation layer 10, they may be protected by the filling layer 20, and accordingly, a forming process of an additional protective layer for protecting the antenna 100 and the electronic element 200 may be omitted.

Hereinafter, an antenna apparatus according to another example will be described with reference to FIG. 14. FIG. 14 illustrates a cross-sectional view of an antenna apparatus according to another example.

Referring to FIG. 14, the antenna apparatus 2000b has some similar features to the antenna apparatus 2000 described above with reference to FIG. 12. A detailed description of same constituent elements will be omitted.

As illustrated in FIG. 14, the antenna apparatus 2000b includes an antenna 100 and an electronic element 200 positioned in the first cavity 11 and the second cavity 12 of the first insulation layer 10 to be spaced apart from each other by an insulating side wall 10aa. The first insulation layer 10 has a first surface 10a and a second surface 10b positioned at opposite sides in parallel to the third direction z, the antenna 100 has a third surface 101 positioned in a direction that faces the third direction z like the first surface 10a of the first insulation layer 10, and similarly, the electronic element 200 has a fourth surface 201 positioned in the direction that faces the third direction z like the first surface 10a of the first insulation layer 10.

A height of the first surface 10a of the first insulation layer 10 is almost the same as that of the third surface 101 of the antenna 100 and that of the fourth surface 201 of the electronic element 200, and thus the surfaces 10a, 101, and 201 may be substantially coplanar.

A filling layer 20 is filled between the first cavity 11 and the second cavity 12 of the first insulation layer 10 and between the antenna 100 and electronic element 200.

The filling layer 20 may have a second contact hole 22, which is formed in the surface 20a facing the third direction z like the first surface 10a of the first insulation layer 10 to expose a portion of the second contact pad 2 of the electronic element 200.

A connecting layer 40 having a slot 41 is disposed on the surface 20a of the filling layer 20.

The connector 300 is disposed in a surface of the connecting layer 40 facing the third direction z, and a power supply wire 50 that is connected to the electronic element 200 through the contact hole 31a that is aligned with the second contact hole 22 is disposed between the second insulation layer 3a and the third insulation layer 3b of the connector 300.

When power is supplied from the electronic element 200 through the power supply wire 50, the connecting layer 40 having the slot 41 is coupled to the power supply wire 50 to receive an electromagnetic field to be coupled with the antenna 100, thereby supplying power to the antenna. This feeding method is referred to as slot feeding. A size and a shape of the slot 41 of the connecting layer 40 may be changed depending on a resonance frequency of the antenna.

As such, the antenna 100 and the electronic element 200 of the antenna apparatus 2000b are disposed in the first cavity 11 and the second cavity 12 of the first insulation layer 10, thereby reducing a volume occupied by the antenna apparatus 2000b compared with a case where the antenna 100 and the electronic element 200 are disposed to vertically overlap each other along the third direction z. In addition, the antenna 100 and the electronic element 200 may be electrically connected to each other without using an additional electrical connection member, such as a solder ball, and thus it is possible to prevent the characteristic of the antenna from being deteriorated or the antenna loss caused by the electrical connection member.

In addition, the antenna 100 and the electronic element 200 of the antenna apparatus 2000b may be disposed in the first cavity 11 and the second cavity 12 of the first insulation layer 10, they may be protected by the filling layer 20, and accordingly, a forming process of an additional protective layer for protecting the antenna 100 and the electronic element 200 may be omitted.

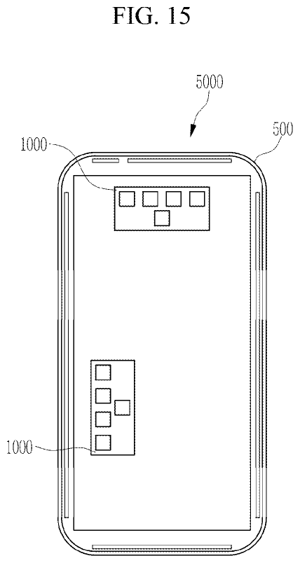

Hereinafter, an electronic device including an antenna apparatus according to an example will be briefly described with reference to FIG. 15. FIG. 15 illustrates a schematic diagram of an electronic device including an antenna apparatus according to an example.

Referring to FIG. 15, the electronic device 5000 includes an antenna apparatus 1000, and the antenna apparatus 1000 is disposed on a set substrate 500 of the electronic device 5000.

The electronic device 5000 may have polygonal sides, and the antenna apparatus 1000 may be disposed adjacent to at least some of the sides of the electronic device 5000.

The electronic device 5000 may be a smart phone, a personal digital assistant, a digital video camera, a digital still camera, a network system, a computer, a monitor, a tablet, a laptop, a network, a television, a video game, a smart watch, an automotive device, or the like, and the present invention is not limited thereto.

The antenna apparatus 1000 includes an antenna embedded in a cavity of an insulation layer and an electronic element for transferring an electronic signal to the antenna, and the electronic element may be an integrated circuit. The electronic device 5000 may further include an integrated circuit such as a communication module and a baseband circuit.

As described above, the electronic device 5000 may include the antenna 100 embedded in a cavity of the insulation layer and the electronic element 200 that transfers the electronic signal to the antenna, thereby requiring no connection member such as a solder ball, and thus they may be easily installed in the electronic device 5000, and a volume of the electronic device 5000 may not be increased.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An antenna apparatus comprising:
a first insulation layer defining a cavity;
an antenna and an electronic element disposed in the cavity of the first insulation layer;
a second insulation layer disposed on a first surface facing a first direction among surfaces of the antenna and on a second surface facing the first direction among surfaces of the electronic element; and
a connection wire disposed on a third surface facing the first direction among surfaces of the second insulation layer and configured to electrically connect the antenna and the electronic element,
wherein the connection wire is disposed on the second insulation layer, is disposed within a first contact hole overlapping the electronic element, and overlaps the antenna.

2. The antenna apparatus of claim 1, wherein
the second insulation layer comprises second contact hole overlapping the antenna, and
the antenna and the electronic element are configured to be connected to each other through the first contact hole, the second contact hole, and the connection wire.

3. The antenna apparatus of claim 2, wherein
the connection wire is disposed to contact the third surface of the second insulation layer closest to the first surface of the antenna and the second surface of the electronic element.

4. The antenna apparatus of claim 1, wherein
the antenna is a dielectric material resonator antenna.

5. The antenna apparatus of claim 1, wherein
the connection wire overlaps the antenna along the first direction.

6. The antenna apparatus of claim 5, further comprising:
a connection layer disposed between the connection wire and the antenna, and comprising a slot,
wherein the slot of the connection layer overlaps the antenna along the first direction.

7. The antenna apparatus of claim 1, wherein
the antenna and the electronic element are separated by a side wall, and
the side wall includes the first insulation layer.

8. The antenna apparatus of claim 1, wherein
the first insulation layer comprises a first sublayer, a second sublayer, and an intermediate layer disposed between the first sublayer and the second sublayer.

9. The antenna apparatus of claim 8, wherein
the cavity of the first insulation layer includes a first cavity and a second cavity separated from the first cavity,
the first cavity is formed in the first sublayer, the intermediate layer, and the second sublayer and the second cavity is formed in the first sublayer, and
the antenna is disposed in the first cavity, and the electronic element is disposed in the second cavity.

10. The antenna apparatus of claim 1, wherein
a fourth surface facing the first direction among the surfaces of the first insulation layer is coplanar with the first surface of the antenna and the second surface of the electronic element.

11. An antenna apparatus comprising:
a first insulation layer;
an antenna disposed within a first cavity of the first insulation layer;
an electronic element disposed in a second cavity of the first insulation layer;
a connection wire configured to electrically connect the antenna and the electronic element; and
a second insulation layer disposed between the antenna, the electronic element, and the connection wire, and comprising a first contact hole overlapping the antenna and a second contact hole overlapping the electronic element,
wherein the antenna is connected to the electronic element through the first contact hole, the connection wire, and the second contact hole.

12. The antenna apparatus of claim 11, wherein
the connection wire is disposed to contact a second insulation layer closest to the surface of the antenna and the surface of the electronic element.

13. The antenna apparatus of claim 11, wherein
the antenna is a dielectric material resonator antenna.

14. The antenna apparatus of claim 11, wherein
the antenna and the electronic element are separated by a side wall, and
the side wall includes the first insulation layer.

15. The antenna apparatus of claim 11, wherein
the first insulation layer comprises a first sublayer, a second sublayer, and an intermediate layer disposed between the first sublayer and the second sublayer.

16. The antenna apparatus of claim 15, wherein
the first cavity is separated from the second cavity,
the first cavity is formed in the first sublayer, the intermediate layer, and the second sublayer and the second cavity is formed in the first sublayer, and
the antenna is disposed in the first cavity, and the electronic element is disposed in the second cavity.

17. An antenna apparatus comprising:
an antenna disposed in a first cavity of an insulation layer;
an electronic element disposed in a second cavity of the insulation layer such that a first surface of the electronic element is coplanar with a first surface of the antenna; and
a connection wire disposed opposite the first surface of the antenna and the first surface of the electronic element and configured to electrically connect the antenna and the electronic element.

18. The antenna apparatus of claim 17, further comprising a connector disposed opposite the first surface of the antenna and the first surface of the electronic element, wherein the connection wire is disposed within an insulation layer of the connector.
